(19) United States
(12) Patent Application Publication
(10) Pub. No.: US 2026/0354050 A1
(43) Pub. Date: Nov. 5, 2026

(54) SEMICONDUTOR DEVICE

(71) Applicant: SK hynix Inc., Icheon (KR)

(72) Inventors: Kyung Seop KIM, Icheon (KR); Chi Ho Kim, Icheon (KR); Young Cheol Song, Icheon (KR); Jae Wan Choi, Icheon (KR)

(21) Appl. No.: 19/740,065

(22) Filed: Jul. 13, 2026

Related U.S. Application Data
(63) Continuation of application No. 18/347,418, filed on Jul. 5, 2023.

(30) Foreign Application Priority Data
Dec. 21, 2022 (KR) 10-2022-0180405

(51) Int. Cl. H10N 70/00; H10B 63/00

(52) U.S. Cl. CPC H10N 70/883; H10B 63/84; H10N 70/023; H10N 70/063; H10N 70/826; H10N 70/841

(57) ABSTRACT

A semiconductor device is provided. The semiconductor device according to an implementation of the disclosed technology May include a selector layer; a first protective layer disposed on sidewalls of the selector layer, the first protective layer including silicon (Si) and nitrogen (N) and having a nitrogen (N) content higher than a silicon (Si) content; and a second protective layer disposed over the first protective layer, the second protective layer including silicon (Si) and nitrogen (N) and having a silicon (Si) content higher than a nitrogen (N) content.

### CROSS-REFERENCE TO RELATED APPLICATIONS

This patent document is a continuation of U.S. patent application Ser. No. 18/347,418, entitled “SEMICONDUCTOR DEVICE” and filed on Jul. 5, 2023, which claims the priority and benefits of Korean Patent Application No. 10-2022-0180405, entitled “SEMICONDUCTOR DEVICE” and filed on Dec. 21, 2022. The entire disclosures of the above applications are incorporated herein by reference.

### TECHNICAL FIELD

Embodiments of the disclosed technology relate to memory circuits or devices and their applications in semiconductor devices or systems.

### BACKGROUND

As electronic devices such as personal computers, mobile devices, or the like trend toward miniaturization, low power consumption, high performance, multi-functionality, memory devices capable of storing data in various electronic devices have been in demand. Thus, research has been conducted for developing memory devices having switching characteristics, i.e., devices capable of storing data by switching between different resistance states according to an applied voltage or current. Examples of memory devices include an RRAM (resistive random access memory), a PRAM (phase change random access memory), an FRAM (ferroelectric random access memory), an MRAM (magnetic random access memory), an E-fuse, and the like.

### SUMMARY

The disclosed technology relates to memory circuits or devices and their applications in semiconductor devices or systems.

In one aspect, a semiconductor device may include a selector layer; a first protective layer disposed on sidewalls of the selector layer, the first protective layer including silicon (Si) and nitrogen (N) and having a nitrogen (N) content higher than a silicon (Si) content; and a second protective layer disposed over the first protective layer, the second protective layer including silicon (Si) and nitrogen (N) and having a silicon (Si) content higher than a nitrogen (N) content.

In another aspect, a semiconductor device may include a first conductive line; a second conductive line disposed over the first conductive line and spaced apart from the first conductive line; a selector layer disposed between the first conductive line and the second conductive line; a first protective layer disposed on sidewalls of the selector layer, the first protective layer including silicon (Si) and nitrogen (N) and having a nitrogen (N) content higher than a silicon (Si) content; and a second protective layer disposed on the first protective layer, the second protective layer including silicon (Si) and nitrogen (N) and having a silicon (Si) content higher than a nitrogen (N) content.

These and other aspects, implementations and associated beneficial aspects are described in greater detail in the drawings, the description, and the claims.

### BRIEF DESCRIPTION OF THE DRAWINGS

FIGS. 1A and 1B illustrate an example of a semiconductor device based on some implementations of the disclosed technology.

FIGS. 2A to 2D are cross-sectional views illustrating an example of a method of fabricating a semiconductor device based on some implementations of the disclosed technology.

FIGS. 3A to 3F are cross-sectional views illustrating another example of a semiconductor device and method of fabricating the semiconductor device based on some implementations of the disclosed technology.

FIG. 4 illustrates another example of a semiconductor device based on some implementations of the disclosed technology.

FIG. 5 illustrates another example of a semiconductor device based on some implementations of the disclosed technology.

FIG. 6 illustrates another example of a semiconductor device based on some implementations of the disclosed technology.

FIG. 7 illustrates another example of a semiconductor device based on some implementations of the disclosed technology.

FIG. 8 illustrates another example of a semiconductor device based on some implementations of the disclosed technology.

FIG. 9 illustrates another example of a semiconductor device based on some implementations of the disclosed technology.

FIGS. 10A and 10B illustrate results of element analysis of a first protective layer and a second protective layer formed according to some implementations of the disclosed technology.

### DETAILED DESCRIPTION

Various examples and implementations of the disclosed technology are described below in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

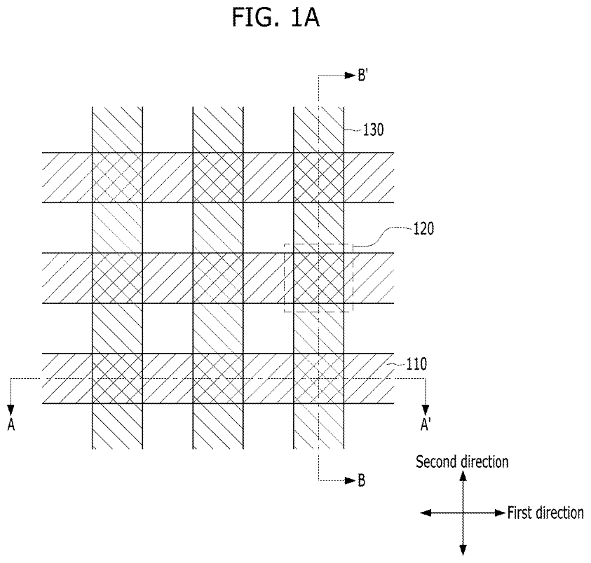

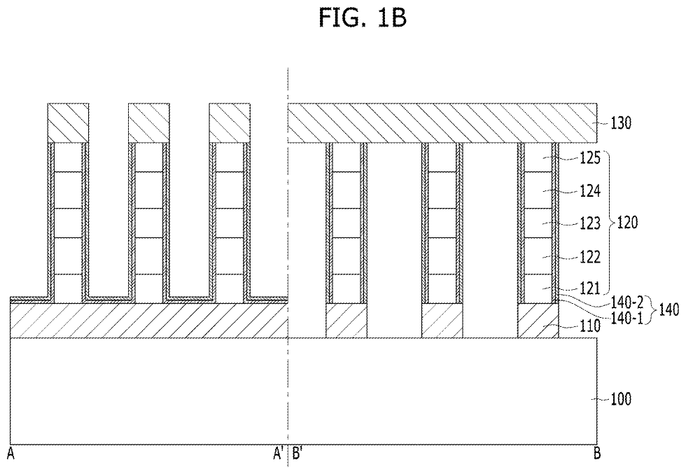

FIGS. 1A and 1B illustrate an example of a semiconductor device based on some implementations of the disclosed technology. FIG. 1A is a plan view and FIG. 1B shows cross-sectional views taken along line A-A′ and line B-B′ of FIG. 1A, respectively.

Referring to FIGS. 1A and 1B, the semiconductor device may include a substrate 100, first conductive lines 110 formed over the substrate 100 and extending in a first direction, second conductive lines 130 formed over the first conductive lines 110 to be spaced apart from the first conductive lines 110 in a third direction (or vertical direction) and extending in a second direction crossing the first direction, and memory cells 120 disposed at intersections of the first conductive lines 110 and the second conductive lines 130 between the first conductive lines 110 and the second conductive lines 130 in the third direction. The third direction is perpendicular to a top surface of the substrate 100, and crosses the first direction and the second direction.

The semiconductor device may have a cross-point structure where a memory cell resides at every intersection of the first conductive lines and the second conductive lines. In this patent document, the conductive lines can indicate conductive structures that electrically connect two or more circuit elements to each other in the semiconductor device. In some implementations, the conductive lines include word lines that are used to control access to memory cells in the semiconductor device and bit lines that are used to read out information stored in the memory cells. In some implementations, the conductive lines include interconnects that carry signals between different circuit elements in the semiconductor device.

The substrate 100 may include a semiconductor material such as silicon. A required lower structure (not shown) may be formed in the substrate 100. For example, the substrate 100 may include a driving circuit (not shown) electrically connected to the first conductive lines 110 and/or to the second conductive lines 130 to control operations of the memory cells 120.

A first conductive line 110 and a second conductive line 130 may be connected to a lower end and an upper end of a corresponding memory cell 120, respectively, and may provide a voltage or a current to the corresponding memory cell 120 to drive the corresponding memory cell 120. When the first conductive line 110 functions as a word line, the second conductive line 130 may function as a bit line. Conversely, when the first conductive line 110 functions as a bit line, the second conductive line 130 may function as a word line.

The first conductive line 110 and the second conductive line 130 each may include a single-layered structure or a multi-layered structure including one or more of various conductive materials. Examples of the conductive materials may include a metal, a metal nitride, a conductive carbon material, and a combination thereof, but implementations thereof are not limited thereto. For example, the first conductive line 110 and the second conductive line 130 each may include tungsten (W), titanium (Ti), tantalum (Ta), platinum (Pt), aluminum (Al), copper (Cu), zinc (Zn), nickel (Ni), cobalt (Co), lead (Pb), tungsten nitride (WN), tungsten silicide (WSi), titanium nitride (TIN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SIC), or silicon carbon nitride (SiCN), or a combination thereof.

The memory cells 120 may be arranged in a matrix form having rows and columns along the first direction and the second direction so as to overlap the intersections of the first conductive lines 110 and the second conductive lines 130. In an implementation, each of the memory cells 120 may have a size that is substantially equal to or smaller than that of an intersection region between each corresponding pair of the first conductive lines 110 and the second conductive lines 130. In another implementation, each of the memory cells 10 may have a size that is larger than that of an intersection region between each corresponding pair of the first conductive lines 110 and the second conductive lines 130.

In some implementations, the memory cell 120 may have a cylindrical shape or a square pillar shape, but the shape of the memory cell 120 is not limited thereto.

Spaces between the first conductive lines 110, the second conductive lines 130, and the memory cells 120 may be filled with an insulating material.

The memory cell 120 may include a stacked structure including a lower electrode layer 121, a selector layer 122, a-middle electrode layer 123, a variable resistance layer 124, and an upper electrode layer 125.

The lower electrode layer 121 may be interposed between the first conductive line 110 and the selector layer 122 and disposed at a lowermost portion of the memory cell 120. The lower electrode layer 121 may function as a circuit node that carries a current or applies a voltage between the first conductive line 110 and the remaining portions (e.g., the layers 122, 123, 124, and 125) of the memory cell 120.

The middle electrode layer 123 may be interposed between the selector layer 122 and the variable resistance layer 124. The intermediate electrode layer 123 may electrically connect the selector layer 122 and the variable resistance layer 124 to each other while physically isolating or separating the selector layer 122 and the variable resistance layer 124 from each other.

The upper electrode layer 125 may be disposed at an uppermost portion of the memory cell 120 and function as a transmission path of an electrical signal such as a voltage or a current between the memory cell 120 and the second conductive line 130.

The lower electrode layer 121, the middleelectrode layer 123, and the upper electrode layer 125 each may include a single-layered structure or a multi-layered structure including various conductive materials such as a metal, a metal nitride, a conductive carbon material, or a combination thereof. For example, the lower electrode layer 121, the middle electrode layer 123, and the upper electrode layer 125 each may include tungsten (W), titanium (Ti), tantalum (Ta), platinum (Pt), aluminum (Al), copper (Cu), zinc (Zn), nickel (Ni), cobalt (Co), lead (Pb), tungsten nitride (WN), tungsten silicide (WSi), titanium nitride (TIN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SiC), or silicon carbon nitride (SiCN), or a combination thereof.

The lower electrode layer 121, the middle electrode layer 123, and the upper electrode layer 125 may include the same material as each other or different materials from each other.

The lower electrode layer 121, the middle electrode layer 123, and the upper electrode layer 125 may have the same thickness as each other or different thicknesses from each other.

At least one of the lower electrode layer 121, the middle electrode layer 123, or the upper electrode layer 125 may be omitted. In some implementations, when the lower electrode layer 121 is omitted, the first conductive line 110 may perform the function of the lower electrode layer 121. In some implementations, when the upper electrode layer 125 is omitted, the second conductive line 130 may perform the function of the upper electrode layer 125.

The selector layer 122 may serve to control access to the variable resistance layer 124 and prevent a current leakage between memory cells 120 sharing the first line 110 or the second line 130. To this end, the selector layer 122 may have a threshold switching characteristic that blocks or substantially limits a current flowing therethrough when a magnitude of an applied voltage is less than a predetermined threshold value and allows the current to increase rapidly when the magnitude of the applied voltage is equal to or greater than the predetermined threshold value. This threshold value may be referred to as a threshold voltage, and the selector layer 122 may be controlled to be in either a turned-on or “on” state to be electrically conductive or a turned-off or “off” state to be electrically less-conductive than the “on” state or electrically non-conductive depending on whether the applied voltage is above or below the threshold voltage, respectively. That is, by controlling the applied voltage relative to the threshold voltage, the selector layer 122 exhibits different conductive states providing a switching operation in which the selector layer 122 switches between the different conductive states.

The selector layer 122 may include a Metal Insulator Transition (MIT) material such as NbO₂, TiO₂, VO₂, WO₂, or others, a Mixed Ion-Electron Conducting (MIEC) material such as ZrO₂ (Y₂O₃), Bi₂O₃—BaO, (La₂O₃)ₓ(CeO₂)₁₋ₓ, or others, an Ovonic Threshold Switching (OTS) material including a chalcogenide material such as Ge₂Sb₂Te₅, As₂Te₃, As₂, As₂Se₃, or others, or a tunneling insulating material such as a silicon oxide, a silicon nitride, a metal oxide, or others. When the selection layer 122 includes a tunneling insulating layer made of the tunneling insulating material, a thickness of the tunneling insulating layer is sufficiently small to allow tunneling of electrons through the tunneling insulating layer under a given voltage or a given current. The selector layer 122 may include a single-layered structure or a multi-layered structure.

In some implementations, the selector layer 122 may perform a threshold switching operation through a doped region formed in a material layer for the selector layer 122. Thus, a size of the doped region may be controlled by an area in which dopants are distributed. The dopants may form trap sites for charge carriers in the material layer for the selector layer 122. The trap sites may capture the charge carriers moving in the selector layer 122 based on an external voltage applied to the selector layer 122. The trap sites thereby provide the threshold switching characteristic and are used to perform the threshold switching operation.

In some implementations, the selector layer 122 may include a dielectric material in which dopants are distributed. The selector layer 122 may include an oxide with dopants, a nitride with dopants, or an oxynitride with dopants, or a combination thereof such as silicon oxide, titanium oxide, aluminum oxide, tungsten oxide, hafnium oxide, tantalum oxide, niobium oxide, silicon nitride, titanium nitride, aluminum nitride, tungsten nitride, hafnium nitride, tantalum nitride, niobium nitride, silicon oxynitride, titanium oxynitride, aluminum oxynitride, tungsten oxynitride, hafnium oxynitride, tantalum oxynitride, or niobium oxynitride, or a combination thereof. The dopants may include an n-type dopant or a p-type dopant, which is doped by an ion implantation process. Examples of the dopants may include one or more of boron (B), nitrogen (N), carbon (C), phosphorous (P), arsenic (As), aluminum (Al), silicon (Si), and germanium (Ge). For example, the selector layer 122 may include an As-doped silicon oxide or a Ge-doped silicon oxide.

The variable resistance layer 124 may be used to store data by switching between different resistance states according to an applied voltage or current. The variable resistance layer 124 may have a single-layered structure or a multi-layered structure including one or more of materials having a variable resistance characteristic used for an RRAM, a PRAM, an MRAM, an FRAM, and others. For example, the variable resistance layer 124 may include a metal oxide such as a transition metal oxide or a perovskite-based oxide, a phase change material such as a chalcogenide-based material, a ferromagnetic material, a ferroelectric material, or others. In some implementations, the variable resistance layer 124 may include a magnetic tunnel junction (MTJ) structure. However, the implementations are not limited thereto, and the memory cell 120 may include any of other variable resistance layers capable of storing data in various ways instead of the variable resistance layer 124.

In some implementations, the variable resistance layer 124 may include the phase change material. The phase change material may change from a crystalline state to an amorphous state or vice versa according to heat generated while a current flows therein. When the phase change material is in the amorphous state, the phase change material may be in a relatively high resistance state, whereas, when the phase change material is in the crystalline state, the phase change material may be in a relatively low resistance state. As such, the phase change material may be used to store data by switching between the different resistance states, i.e., the high resistance state and the low resistance state, according to an applied voltage or current.

In some implementations, the phase change material may include a chalcogenide material such as Ge—Te, Ge—Sb—Te, Ge—Te—Se, Ge—Te—As, Ge—Te—Sn, Ge—Te—Ti, Ge—Bi—Te, Ge—Sn—Sb—Te, Ge—Sb—Se—Te, Ge—Sb—Te—S, Ge—Te—Sn—O, Ge—Te—Sn—Au, Ge—Te—Sn—Pd, Sb—Te, Se—Te—Sn, Sb—Se—Bi, In—Se, In—Sb—Te, or the like.

In some implementations, each of the memory cells 120 includes the lower electrode layer 121, the selector layer 122, the middle electrode layer 123, the variable resistance layer 124, and the upper electrode layer 125, which are sequentially stacked in the third direction. The structure of the memory cells 120 may be varied without being limited to one as shown in FIGS. 1A and 1B as long as the memory cells 120 have data storage properties.

In some implementations, at least one of the lower electrode layer 121, the middle electrode layer 123, or the upper electrode layer 125 may be omitted. In some implementations, the relative position of the variable resistance layer 124 and the selector layer 122 may be reversed. In some implementations, in addition to the layers 121, 122, 123, 124, and 125 shown in FIG. 1B, each of the memory cells 120 may further include one or more layers (not shown) for enhancing characteristics of the memory cells 120 or improving fabricating processes.

In some implementations, neighboring memory cells among the memory cells 120 may be spaced apart from each other at a predetermined interval, and trenches may be present between the memory cells 120. A trench between two neighboring memory cells 120 may have a height to width ratio (i.e., an aspect ratio) in a range from 1:1 to 40:1, from 10:1 to 40:1, from 10:1 to 20:1, from 5:1 to 10:1, from 10:1 to 15:1, from 1:1 to 25:1, from 1:1 to 30:1, from 1:1 to 35:1, or from 1:1 to 45:1.

In some implementations, the trench may have sidewalls that are substantially perpendicular to the top surface of the substrate 100. In some implementations, neighboring trenches may be spaced apart from each other by the same or similar distance.

Although one cross-point structure disposed over the substrate 100 has been described with reference to FIGS. 1A and 1B, two or more cross-point structures may be stacked in the vertical direction (or third direction) perpendicular to the top surface of the substrate 100.

In some implementations, the semiconductor device may further include a protective layer 140.

The protective layer 140 may be formed on sidewalls of the memory cell 120 and serve to protect the memory cell 120.

In a comparative example, a nitride layer may usually be used as a protective layer to protect a memory cell from chemical and/or physical influences occurring in various subsequent processes after forming the memory cell. However, a process of forming the nitride layer itself may affect the memory cell and cause damage to the memory cell. Moreover, a property of protecting the memory cell from an effect occurring in a subsequent process such as a cleaning process may be deteriorated due to a decrease in chemical stability of the nitride layer. Accordingly, operation characteristics of the memory cell may be adversely affected, thereby deteriorating the characteristic of the semiconductor device.

In order to solve these problems, in some implementations, the protective layer 140 may be formed so as not to damage the memory cell 120 during forming the protective layer 140, and to effectively protect the memory cell 120 from external influences caused by subsequent processes following the process of forming the protective layer 140.

The protective layer 140 may have a double-layered structure including a first protective layer 140-1 and a second protective layer 140-2. In the double-layered structure, the first protective layer 140-1 may be located at an inner portion and the second protective layer 140-2 may be located at an outer portion. The first protective layer 140-1 may be formed on the sidewalls of the memory cell 120 and be configured to suppress damage to the memory cell 120 occurring in the process of forming the first protective layer 140-1. The second protective layer 140-2 may be formed over the first protective layer 140-1 and be configured to protect the memory cell 120 from chemical and/or physical influences occurring in subsequent processes.

In order to perform such a role, when each of the first protective layer 140-1 and the second protective layer 140-2 includes silicon (Si) and nitrogen (N), the first protective layer 140-1 may have a content of nitrogen (N) (hereinafter, referred to as “nitrogen (N) content”) higher than a content of silicon (Si) (hereinafter, referred to as “silicon (Si) content”), and the second protective layer 140-2 may have a silicon (Si) content higher than a nitrogen (N) content. Each of the first protective layer 140-1 and the second protective layer 140-2 may further include components that may not materially affect the essential characteristics of the first protective layer 140-1 and the second protective layer 140-2.

The first protective layer 140-1 may be disposed on the sidewalls of the memory cell 120, and over the first conductive line 110 in the third direction. The first protective layer 140-1 may include silicon (Si) and nitrogen (N) as main components. Since the first protective layer 140-1 having such a composition may be chemically stabilized by forming a bond between silicon (Si) and nitrogen (N), it may not affect the operation of the memory cell 120. Therefore, it is possible to prevent damage to the memory cell 120 during forming the first protective layer 140-1 over the sidewalls of the memory cell 120.

In some implementations, the first protective layer 140-1 may include silicon (Si) and nitrogen (N), and the silicon (Si) content may be 30-45 atomic percent (at %). If the silicon (Si) content in the first protective layer 140-1 is less than 30 at %, there may be a problem in forming a thin film. If the silicon (Si) content in the first protective layer 140-1 is greater than 45 at %, the chemical stability of the first protective layer 140-1 may be lowered, so that silicon (Si) contained in the first protective layer 140-1 may be diffused into the memory cell 120, thereby causing deterioration of the operation characteristic of the memory cell 120.

In some implementations, the first protective layer 140-1 may include at least one of SiN, SiON, SiCN, or SiCON, wherein SiN, SION, SiCN, or SiCON may have the nitrogen (N) content higher than the silicon (Si) content.

The second protective layer 140-2 may be disposed over the first protective layer 140-1. The second protective layer 140-2 may include silicon (Si) and nitrogen (N) as main components and have the silicon (Si) content higher than the nitrogen (N) content. The second protective layer 140-2 having such a composition may have an increased resistance to chemicals such as cleaning solutions used in subsequent processes, thereby effectively protecting the memory cell 120 from chemical and/or physical influences caused by the subsequent processes.

In some implementations, the second protective layer 140-2 may include silicon (Si) and nitrogen (N), and the silicon (Si) content may be 50-70 at %. If the silicon (Si) content in the second protective layer 140-2 is less than 50 at %, the second protective layer 140-2 may not have sufficient resistance to the chemical and/or physical influences caused by the subsequent processes, so that the memory cell 120 may not be sufficiently protected from such influences. If the silicon (Si) content in the second protective layer 140-2 is greater than 70 at %, the second protective layer 140-2 may become a layer having completely different characteristics and thus may not function as the second protective layer 140-2 exhibiting desired properties.

In some implementations, the second protective layer 140-2 may include at least one of SiN, SiON, SiCN, or SiCON, wherein SiN, SiON, SiCN or SiCON may have the silicon (Si) content higher than the nitrogen (N) content.

If the protective layer 140 is too thin, the protective layer 140 may be removed during a subsequent process or the function of the protective layer 140 may be deteriorated, so that a protective effect on the memory cell 120 may be insufficient. On the other hand, if the protective layer 140 is too thick, gaps between the memory cells 120 may be too narrow. Considering these aspects, in some implementations, each of the first protective layer 140-1 and the second protective layer 140-2 may have a thickness in a range of 1-5 nm.

As described above, since the first protective layer 140-1 has chemical stability, it may not cause changes in the memory cell 120 and thus may not affect the operation characteristics of the semiconductor device. Since the second protective layer 140-2 has strong resistance to chemical and/or physical influences, it can effectively protect the memory cell 120 from damages that may be caused by subsequent processes. Accordingly, it is possible to effectively improve the operation characteristics of the memory cell 120, such as a read window margin (RWM) and drift characteristics.

A drift phenomenon may represent a phenomenon in which, when a phase change material used in a PCRAM is switched to an amorphous phase, resistance of the phase change material is increased. The increase in resistance due to the drift has an exponential function with respect to time and has random characteristics within a certain range. Because of this random characteristic, a resistance value of the phase change material may exceed a target value after a certain period of time has elapsed, resulting in a defect of the semiconductor device. In accordance with some implementations, the protective layer 140 including the first protective layer 140-1 and the second protective layer 140-2 may not affect the operation characteristic of the memory cell 120 and can effectively prevent the memory cell 120 from being damaged by the subsequent processes. As a result, it is possible to significantly reduce the drift phenomenon.

In an element in which the selector layer 122 and the variable resistance layer 124 are disposed at a lower portion and an upper portion, respectively, an array size may be increased as an RWM is increased. Therefore, it is important to secure a sufficient RWM. In this regard, if the element exhibits the drift phenomenon, the RWM is reduced compared to the case where the drift phenomenon is not present, and thus the array size is reduced. In accordance with some implementations, the protective layer 140 including the first protective layer 140-1 and the second protective layer 140-2 may not affect the operation of the memory cell 120 and can effectively prevent damages to the memory cell 120 that are caused by the subsequent processes. As a result, it is possible to significantly improve the drift phenomenon and secure the sufficient RWM.

Table 1 shows effects of improving the RWM and drift characteristics according to an example of the protective layer 140 including the first protective layer 140-1 and the second protective layer 140-2. A comparative example represents a nitride single layer.

TABLE 1

Drift (mV)

| | RWM (mV) | SET | RESET |
|---|---|---|---|
| Comparative example | 557 | 226 | 296 |
| Example | 578 | 215 | 281 |

As shown in Table 1, in case of the protective layer 140 having the double-layered structure, the RWM is significantly increased and the drift phenomenon is reduced, compared to the comparative example using the nitride single layer.

The semiconductor device may include other layers in addition to the first conductive line 110, the memory cell 120, and the second conductive line 130. For example, the semiconductor device may further include a lower electrode contact disposed between the first conductive line 110 and the lower electrode layer 121 and/or an upper electrode contact disposed between the second conductive line 130 and the upper electrode layer 125.

Although one cross-point structure has been described, two or more cross-point structures may be stacked in the vertical direction perpendicular to the top surface of the substrate 100.

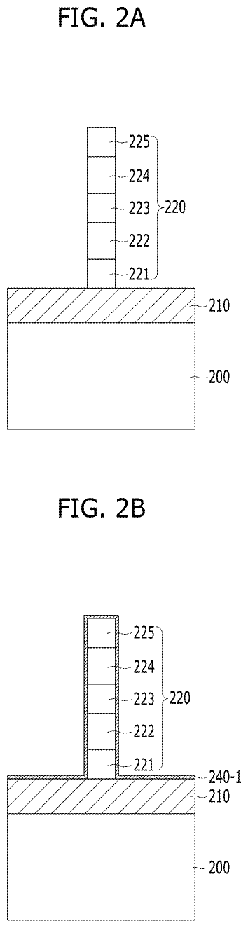

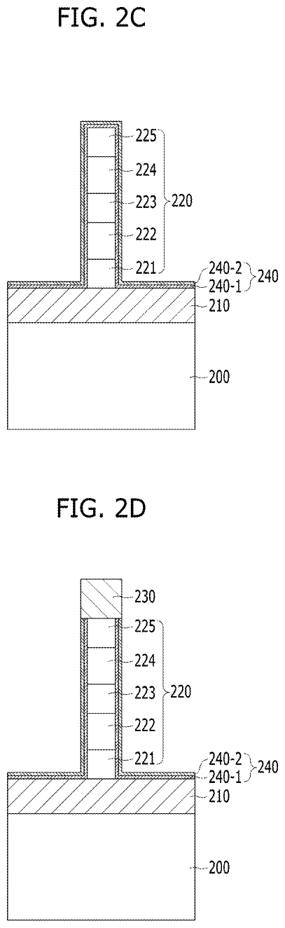

A method of fabricating a semiconductor device will be explained with reference to FIGS. 2A to 2D. The detailed descriptions similar to those described with reference to FIGS. 1A and 1B will be omitted.

FIGS. 2A to 2D are cross-sectional views illustrating an example method of fabricating a semiconductor device based on some implementations of the disclosed technology.

Referring to FIG. 2A, first conductive lines 210 may be formed over a substrate 200 in which a required lower structure is formed. For example, the first conductive lines 210 may be formed by depositing a conductive layer over the substrate 200 and etching the conductive layer using a mask pattern in a line shape extending in a first direction.

A memory cell 220 may be formed over a corresponding one of the first conductive lines 210. For example, the memory cell 220 may be formed by forming a material layer for a lower electrode layer 221, a material layer for a selector layer 222, a material layer for a middle electrode layer 223, a material layer for a variable resistance layer 224, and a material layer for an upper electrode layer 225 and by etching the material layers using a mask pattern (not shown). In some implementations, the memory cell 220 may have a pillar-type island shape.

Referring to FIG. 2B, a first protective layer 240-1 may be formed along a profile of the structure of FIG. 2A. The first protective layer 240-1 may include silicon (Si) and nitrogen (N) and have a nitrogen (N) content higher than a silicon (Si) content. In some implementations, the first protective layer 240-1 may have the silicon (Si) content in a range of 30-45 at %. In some implementations, the first protective layer 240-1 may include at least one of SiN, SiON, SiCN, or SiCON, wherein SiN, SiON, SiCN, or SiCON may have a nitrogen (N) content higher than a silicon (Si) content. In some implementations, the first protective layer 240-1 may have a thickness of 1-5 nm.

The first protective layer 240-1 may be formed by using a deposition process known in the art, for example, using a chemical vapor deposition (PVD) process or an atomic layer deposition (ALD) process.

In some implementations, the first protective layer 240-1 may be formed by a plasma enhanced chemical vapor deposition (PECVD) process. For example, the first protective layer 240-1 may be formed by the PECVD process using SiH₄ at a flow rate of 50-200 sccm, NH₃ at a flow rate of 200-800 sccm, and plasma discharge power of 50-300 W.

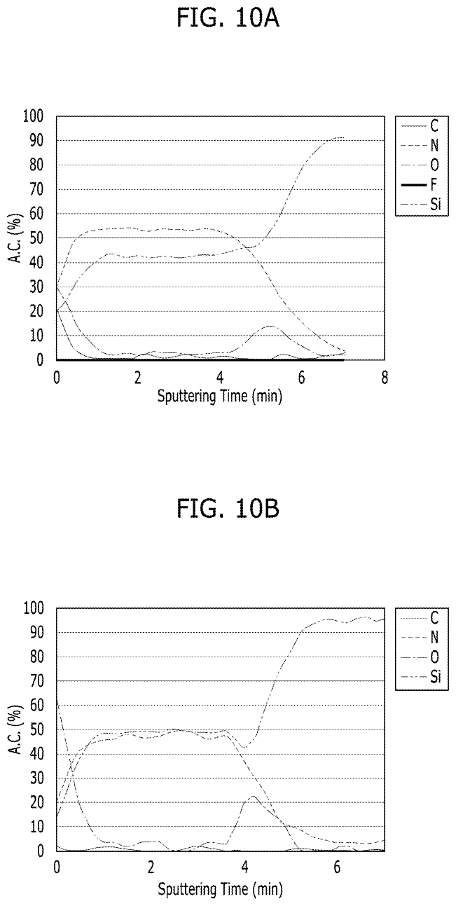

FIG. 10A illustrates results of component analysis of an example of the first protective layer 240-1 formed by such a process. FIG. 10A shows results obtained by analyzing a content (at %) of each element in the first protective layer 240-1 according to a sputtering time while sputtering the first protective layer 240-1. It can be seen from FIG. 10A that the first protective layer 240-1 includes a nitrogen (N) content higher than a silicon (Si) content in a certain range of the sputtering time, e.g., before the sputtering time reaches around 5 minutes.

Referring to FIG. 2C, a second protective layer 240-2 may be formed over the first protective layer 240-1. The second protective layer 240-2 may include silicon (Si) and nitrogen (N) and have a (Si) content higher than a nitrogen (N) content. In some implementations, the silicon (Si) content may be 50-70 at %. In some implementations, the second protective layer 240-2 may include SiN, SION, SiCN, or SiCON, wherein SiN, SION, SiCN or SiCON may have a silicon (Si) content higher than a nitrogen (N) content. In some implementations, the second protective layer 240-2 may have a thickness of 1-5 nm.

The second protective layer 240-2 may be formed by using a deposition process known in the art, for example, using a chemical vapor deposition (PVD) process or an atomic layer deposition (ALD) process.

In some implementations, the second protective layer 240-2 may be formed by the PECVD process using SiH₄ at a flow rate of 200-500 sccm, NH₃ at a flow rate of 30-300 sccm, and plasma discharge power of 50-300 W.

FIG. 10B illustrates results of component analysis of an example of the second protective layer 240-2 formed by such a process. FIG. 10B shows results obtained by analyzing a content (at %) of each element in the second protective layer 240-2 according to a sputtering time while sputtering the second protective layer 240-2. It can be seen from FIG. 10B that the second protective layer 240-2 includes silicon (Si) and nitrogen (N) and has a silicon (Si) content higher than a nitrogen (N) content in a certain range of the sputtering time, e.g., after the sputtering time reaches around 0.7 minutes.

The first protective layer 240-1 and the second protective layer 240-2 may form a protective layer 240.

Referring to FIG. 2D, second conductive lines 230 may be formed over the memory cells 220. At this time, the first protective layer 240-1 and the second protective layer 240-2 disposed over the upper electrode layer 225 may be removed before forming the second conductive lines 230.

In some implementations, the second conductive lines 230 may be formed by depositing a conductive layer for the second conductive lines 230 over the memory cells 220 and etching the conductive layer using a mask pattern in a line shape extending in a second direction.

In some implementations, an insulating layer may be formed to cover the structure of FIG. 2C, and the insulating layer may be planarized until a top surface of the upper electrode layer 225 is exposed. Thereafter, the conductive layer for the second conductive lines 230 may be formed on a structure obtained by planarizing the insulating layer, and the conductive layer may be etched using the mask pattern to have the line shape extending in the second direction. However, implementations are not limited thereto.

Through the above processes, the semiconductor device including the first conductive lines 210, the memory cells 220, the second conductive lines 230, and the protective layer 240 may be formed. The memory cell 220 may include the lower electrode layer 221, the selector layer 222, the middle electrode layer 223, the variable resistance layer 224, and the upper electrode layer 225, which are sequentially stacked. The protective layer 240 may include the first protective layer 240-1 disposed on the sidewalls of the memory cell 220 and the second protective layer 240-2 disposed over the first protective layer 240-1. The first protective layer 240-1 and the second protective layer 240-2 are formed over the first conductive line 210 in the third direction.

In accordance with some implementations, the protective layer 240 having the double-layered structure including the first protective layer 240-1 and the second protective layer 240-2 may be formed on the sidewalls of the memory cell 220. The first protective layer 240-1 may include silicon (Si) and nitrogen (N) and have a the nitrogen (N) content higher than the silicon (Si) content. The first protective layer 240-1 is chemically stabilized and does not affect the operation characteristic of the memory cell 220, thereby preventing damage to the memory cell 220. The second protective layer 240-2 may include silicon (Si) and nitrogen (N) and have the silicon (Si) content higher than the nitrogen (N) content. The second protective layer 240-2 has strong resistance to chemicals such as cleaning solutions used in the subsequent processes, thereby effectively protecting the memory cell 220 from chemical and/or physical influences caused by the subsequent processes. That is, in some implementations, by forming the protective layer 240, both damage to the memory cell 220 caused by the process for forming the protective layer 240 and damage to the memory cell 120 from external factors caused by the subsequent processes can be effectively prevented. As a result, it is possible to significantly improve the operation characteristics of the memory cell 220, such as the RWM and drift characteristics.

The substrate 200, the first conductive line 210, the memory cell 220, the lower electrode layer 221, the selector layer 222, the middle electrode layer 223, the variable resistance layer 224, the upper electrode layer 225, the second conductive line 230, the first protective layer 240-1, the second protective layer 240-2, and the protective layer 240 shown in FIG. 2D may correspond to the substrate 100, the first conductive line 110, the memory cell 120, the lower electrode layer 121, the selector layer 122, the middle electrode layer 123, the variable resistance layer 124, the upper electrode layer 125, the second conductive line 130, the first protective layer 140-1, the second protective layer 140-2, and the protective layer 140 shown in FIG. 1B, respectively.

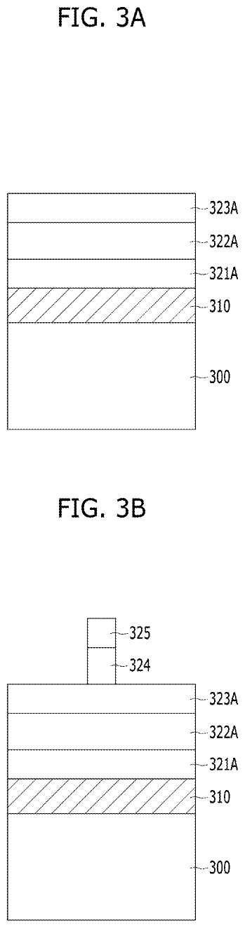

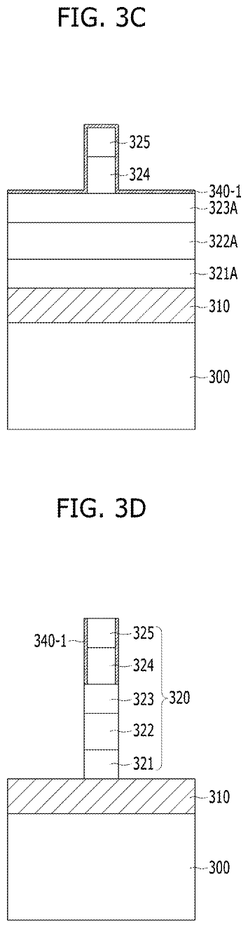

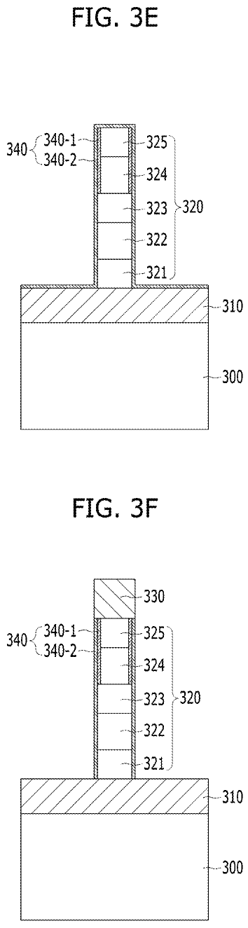

In the implementations shown in FIGS. 1A and 1B and FIGS. 2A to 2D, each of the protective layers 140 and 240 is formed on the entire sidewalls of each of the memory cells 120 and 220. However, in other implementations, each of the first protective layers 140-1 and 240-1 may be formed on a part of the sidewalls of each of the memory cells 120 and 220. This will be described in detail with reference to FIGS. 3A to 3F.

FIGS. 3A to 3F illustrate another example of a semiconductor device and a method of fabricating the semiconductor device based on some implementations of the disclosed technology. The implementation shown in FIGS. 3A to 3F may be similar to the implementations shown in FIGS. 1A and 1B and FIGS. 2A to 2D except that a first protective layer 340-1 is formed on a part of sidewalls of a memory cell 320. The descriptions similar to those of the implementations shown in FIGS. 1A and 1B and FIGS. 2A to 2D will be omitted.

Referring to FIG. 3A, first conductive lines 310 may be formed over a substrate 300. A material layer 321A for forming a lower electrode layer, a material layer 322A for forming a selector layer, and a material layer 323A for forming a middle electrode layer may be sequentially formed over the first conductive lines 310.

Referring to FIG. 3B, a variable resistance layer 324 and an upper electrode layer 325 which are sequentially stacked may be formed over the material layer 323A. The variable resistance layer 324 and the upper electrode layer 325 may be formed by forming a material layer for forming the variable resistance layer 324 and a material layer for forming the upper electrode layer 325 over the material layer 323A and sequentially etching the material layers using a mask pattern (not shown).

Referring to FIG. 3C, the first protective layer 340-1 may be formed along a profile of the structure of FIG. 3C. That is, the first protective layer 340-1 may be formed to surround the variable resistance layer 324 and the upper electrode layer 325 and cover the material layer 323A. The first protective layer 340-1 may correspond to the first protective layer 140-1 of FIG. 1B and the first protective layer 240-1 of FIG. 2B.

The first protective layer 340-1 may include silicon (Si) and nitrogen (N) as main components and have a nitrogen (N) content higher than a silicon (Si) content. In some implementations, the silicon (Si) content may be 30-45 at %. In some implementations, the first protective layer 340-1 may include at least one of SiN, SiON, SiCN, or SiCON, wherein SiN, SION, SiCN, or SiCON may have a nitrogen (N) content higher than a silicon (Si) content.

The first protective layer 340-1 may be formed by using a deposition process known in the art, for example, using a chemical vapor deposition (PVD) process or an atomic layer deposition (ALD) process.

In some implementations, the first protective layer 340-1 may be formed by a plasma enhanced chemical vapor deposition (PECVD) process. For example, the first protective layer 340-1 may be formed by the plasma enhanced chemical vapor deposition (PECVD) process using SiH₄ at a flow rate of 50-200 sccm, NH₃ at a flow rate of 200-800 sccm, and plasma discharge power of 50-300 W.

Referring to FIG. 3D, a lower electrode layer 321, a selector layer 322, and a middle electrode layer 323 may be formed by patterning the material layer 323A, the material layer 322A, and the material layer 321A by using, for example, a spacer patterning technology (SPT). At this time, the first protective layer 340-1 may be etched to remain on sidewalls of the variable resistance layer 324 and sidewalls of the upper electrode layer 325, and the first protective layer 340-1 disposed over the upper electrode layer 325 and over the material layer 323A may be removed.

As such, the memory cell 320 including the lower electrode layer 321, the selector layer 322, the middle electrode layer 323, the variable resistance layer 324, and the upper electrode layer 325, which are sequentially stacked, may be formed. The memory cell 320 may have a pillar-type island shape.

Referring to FIG. 3E, a second protective layer 340-2 may be formed along a profile of the structure of FIG. 3D. That is, the second protective layer 340-2 may be disposed over the first protective layer 340-1, over the upper electrode layer 325, on sidewalls of the lower electrode layer 321, the selector layer 322, and the middle electrode layer 323, and over the first conductive lines 310. The second protective layer 340-2 may correspond to the second protective layer 140-2 of FIG. 1B and the second protective layer 240-2 of FIG. 2D.

The second protective layer 340-2 may include silicon (Si) and nitrogen (N) as main components and have a silicon (Si) content higher than a nitrogen (N) content. In some implementations, the silicon (Si) content may be 50-70 at %. In some implementations, the second protective layer 340-2 may include at least one of SiN, SiON, SiCN, or SiCON, wherein SiN, SION, SiCN or SiCON may have a silicon (Si) content higher than a nitrogen (N) content. In some implementations, the second protective layer 340-2 may have a thickness of 1-5 nm.

The second protective layer 340-2 may be formed by using a deposition process known in the art, for example, a chemical vapor deposition (PVD) process or an atomic layer deposition (ALD) process.

In some implementations, the second protective layer 340-2 may be formed by the PECVD process using SiH₄ at a flow rate of 200-500 sccm, NH₃ at a flow rate of 30-300 sccm, and plasma discharge power of 50-300 W.

The first protective layer 340-1 and the second protective layer 340-2 may form a protective layer 340.

Referring to FIG. 3F, second conductive lines 330 may be formed over the memory cells 320. At this time, before forming the second conductive lines 330, the second protective layer 340-2 over the upper electrode layer 325 and over the first conductive lines 310 may be removed.

Through the above processes, the semiconductor device including the first conductive lines 310, the memory cells 320, the second conductive lines 330, and the protective layer 340 may be formed. The memory cell 320 may include the lower electrode layer 321, the selector layer 322, the middle electrode layer 323, the variable resistance layer 324, and the upper electrode layer 325, which are sequentially stacked. The protective layer 340 may include the first protective layer 340-1 disposed on the sidewalls of the variable resistance layer 324 and the upper electrode layer 325, and the second protective layer 340-2 disposed over the first protective layer 340-1 and on the sidewalls of the lower electrode layer 321, the selector layer 322, and the middle electrode layer 323.

In accordance with some implementations, the protective layer 340 having the double-layered structure including the first protective layer 340-1 and the second protective layer 340-2 may be formed. The first protective layer 340-1 may be disposed over a portion of the sidewalls of the memory cell 320, and the second protective layer 340-2 may be disposed over the first protective layer 340-1 and over the remaining portion of the sidewalls of the memory cell 320. Since the first protective layer 340-1 includes silicon (Si) and nitrogen (N) and has the nitrogen (N) content higher than the silicon (Si) content. The first protective layer 340-1 can be chemically stabilized and does not affect the operation characteristic of the memory cell 320, thereby preventing damage to the memory cell 320. Since the second protective layer 340-2 includes silicon (Si) and nitrogen (N) and has the silicon (Si) content higher than the silicon (Si) content, the second protective layer 340-2 can have strong resistance to chemicals such as cleaning solutions used in subsequent processes, thereby effectively protecting the memory cell 320 from chemical and/or physical influences caused by the subsequent processes.

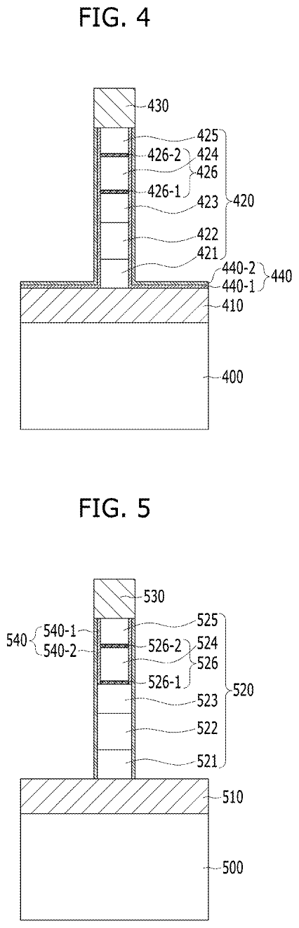

FIGS. 4 to 9 illustrate examples of a semiconductor device based on some implementations of the disclosed technology. The description will be focused on differences from the above-described implementations.

Referring to FIG. 4, a semiconductor device may include a substrate 400, a first conductive line 410, a memory cell 420, a protective layer 440, and a second conductive line 430. The memory cell 420 may include a lower electrode layer 421, a selector layer 422, a middle electrode layer 423, an interfacial electrode layer 426, a variable resistance layer 424, and an upper electrode layer 425. The protective layer 440 may include a first protective layer 440-1 disposed on sidewalls of the memory cell 420 and over the first conductive line 410 and a second protective layer 440-2 disposed over the first protective layer 440-1.

The interfacial electrode layer 426 may include a first interfacial electrode layer 426-1 interposed between the middle electrode layer 423 and the variable resistance layer 424 and a second interfacial electrode layer 426-2 interposed between the variable resistance layer 424 and the upper electrode layer 425.

The first interfacial electrode layer 426-1 may serve to reduce a contact resistance and increase adhesion between the middle electrode layer 423 and the variable resistance layer 424. In some implementations, the first interfacial electrode layer 426-1 may serve to lower a set voltage applied to perform a set operation in which the variable resistance layer 424 changes from a high resistance state to a low resistance state. The first interfacial electrode layer 426-1 may include a conductive material with a low resistance value and a good adhesive property, such as tungsten (W), lithium (Li), aluminum (Al), tin (Sn), bismuth (Bi), antimony (Sb), nickel (Ni), copper (Cu), titanium (Ti), vanadium (V), chromium (Cr), manganese (Mn), iron (Fe), cobalt (Co), zinc (Zn), molybdenum (Mo), or the like.

The second interfacial electrode layer 426-2 may serve to reduce a contact resistance and increase adhesion between the variable resistance layer 424 and the upper electrode layer 425. In some implementations, the second interfacial electrode layer 426-2 may serve to lower the set voltage. The second interfacial electrode layer 426-2 may include a conductive material with a low resistance value and a good adhesive property, such as tungsten (W), lithium (Li), aluminum (Al), tin (Sn), bismuth (Bi), antimony (Sb), nickel (Ni), copper (Cu), titanium (Ti), vanadium (V), chromium (Cr), manganese (Mn), iron (Fe), cobalt (Co), zinc (Zn), molybdenum (Mo), or the like.

Referring to FIG. 5, a semiconductor device may include a substrate 500, a first conductive line 510, a memory cell 520, a protective layer 540, and a second conductive line 530. The memory cell 520 may include a lower electrode layer 521, a selector layer 522, a middle electrode layer 523, an interfacial electrode layer 526, a variable resistance layer 524, and an upper electrode layer 525. The interfacial electrode layer 526 may include a first interfacial electrode layer 526-1 interposed between the middle electrode layer 523 and the variable resistance layer 524 and a second interfacial electrode layer 526-2 interposed between the variable resistance layer 524 and the upper electrode layer 525. The protective layer 540 may include a first protective layer 540-1 disposed on sidewalls of the first interfacial electrode layer 526-1, the variable resistance layer 524, the second interfacial electrode layer 526-2, and the upper electrode layer 525, and a second protective layer 540-2 disposed over the first protective layer 540-1 and on sidewalls of the lower electrode layer 521, the selector layer 522, and the middle electrode layer 523. The first interfacial electrode layer 526-1 and the second interfacial electrode layer 526-2 may correspond to the first interfacial electrode layer 426-1 and the second interfacial electrode layer 426-2 shown in FIG. 4, respectively.

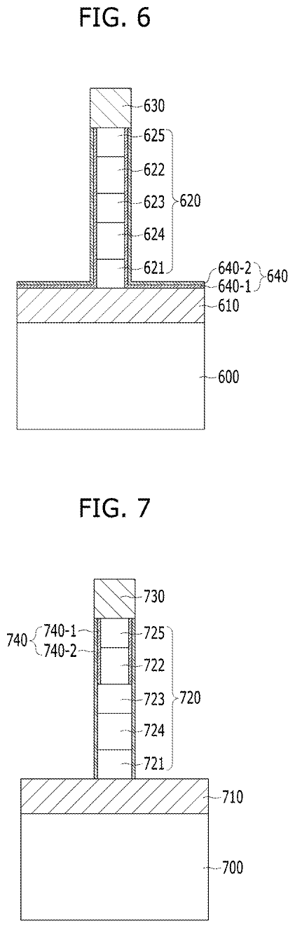

In the above-described implementations, the variable resistance layers 124, 224, 324, 424, and 524 are formed over the selector layers 122, 222, 322, 422, and 522, respectively. However, the relative position of the variable resistance layer and the selector layer may be reversed. This will be described with reference to FIGS. 6 to 9.

Referring to FIG. 6, a semiconductor device may include a substrate 600, a first conductive line 610, a memory cell 620, a protective layer 640, and a second conductive line 630. The memory cell 620 may include a lower electrode layer 621, a variable resistance layer 624, a middle electrode layer 623, a selector layer 622, and an upper electrode layer 625, which are sequentially stacked. The protective layer 640 may include a first protective layer 640-1 disposed on sidewalls of the memory cell 620 and over the first conductive line 610, and a second protective layer 640-2 disposed over the first protective layer 640-1.

Referring to FIG. 7, a semiconductor device may include a substrate 700, a first conductive line 710, a memory cell 720, a protective layer 740, and a second conductive line 730. The memory cell 720 may include a lower electrode layer 721, a variable resistance layer 724, a middle electrode layer 723, a selector layer 722, and an upper electrode layer 725, which are sequentially stacked. The protective layer 740 may include a first protective layer 740-1 disposed on sidewalls of the selector layer 722 and the upper electrode layer 725, and a second protective layer 740-2 disposed over the first protective layer 740-1 and on sidewalls of the lower electrode layer 721, the variable resistance layer 724, and the middle electrode layer 723.

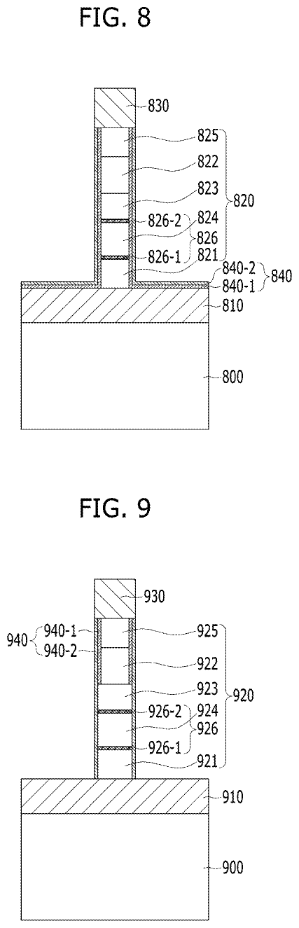

Referring to FIG. 8, a semiconductor device may include a substrate 800, a first conductive line 810, a memory cell 820, a protective layer 840, and a second conductive line 830. The memory cell 820 may include a lower electrode layer 821, a first interfacial electrode layer 826-1, a variable resistance layer 824, a second interfacial electrode layer 826-2, a middle electrode layer 823, a selector layer 822, and an upper electrode layer 825, which are sequentially stacked. The protective layer 840 may include a first protective layer 840-1 disposed on sidewalls of the memory cell 820 and over the first conductive line 810, and a second protective layer 840-2 disposed over the first protective layer 840-1.

Referring to FIG. 9, a semiconductor device may include a substrate 900, a first conductive line 910, a memory cell 920, a protective layer 940, and a second conductive line 930. The memory cell 920 may include a lower electrode layer 921, a first interfacial electrode layer 926-1, a variable resistance layer 924, a second interfacial electrode layer 926-2, a middle electrode layer 923, a selector layer 922, and an upper electrode layer 925, which are sequentially stacked. The protective layer 940 may include a first protective layer 940-1 disposed on sidewalls of the selector layer 922 and the upper electrode layer 925, and a second protective layer 940-2 disposed over the first protective layer 940-1 and on sidewalls of the lower electrode layer 921, the first interfacial electrode layer 926-1, the variable resistance layer 924, the second interfacial electrode layer 926-2, and the middle electrode layer 923.

The semiconductor devices in accordance with the above implementations each may include the protective layer having the double-layered structure that includes the first protective layer and the second protective layer each disposed on all or part of the sidewalls of the memory cell. The first protective layer may include silicon (Si) and nitrogen (N) and have the nitrogen (N) content higher than the silicon (Si) content. The first protective layer can be chemically stabilized and does not affect the operation characteristic of the memory cell, thereby preventing damage to the memory cell. The second protective layer may include silicon (Si) and nitrogen (N) and have the silicon (Si) content higher than the nitrogen (N) content. The second protective layer can have strong resistance to chemicals such as cleaning solutions used in subsequent processes, thereby effectively protecting the memory cell from chemical and/or physical influences caused by the subsequent processes. That is, in the above implementations, by forming the protective layer partly or fully surrounding the memory cell, both damage to the memory cell caused by the process for forming the protective layer and damage to the memory cell from external factors caused by the subsequent processes can be effectively prevented. As a result, it is possible to significantly improve the operation characteristics of the memory cell, such as the RWM and drift characteristics.

Only a few implementations and examples are described above. Accordingly, other implementations, enhancements, and variations can be made based on what is described and illustrated in this patent document.

What is claimed is:

1. A semiconductor device, comprising:
a selector layer;
a first protective layer disposed on sidewalls of the selector layer, the first protective layer including silicon (Si) and nitrogen (N) and having a nitrogen (N) content higher than a silicon (Si) content; and
a second protective layer disposed over the first protective layer, the second protective layer including silicon (Si) and nitrogen (N) and having a silicon (Si) content higher than a nitrogen (N) content.

2. The semiconductor device according to claim 1, wherein the first protective layer includes at least one of SiN, SiON, SiCN, or SiCON.

3. The semiconductor device according to claim 1, wherein the first protective layer has the silicon (Si) content of 30-45 atomic percent (at %).

4. The semiconductor device according to claim 1, wherein the first protective layer has a thickness of 1-5 nm.

5. The semiconductor device according to claim 1, wherein the second protective layer includes at least one of SiN, SiON, SiCN, or SiCON.

6. The semiconductor device according to claim 1, wherein the second protective layer has the silicon (Si) content of 50-70 at %.

7. The semiconductor device according to claim 1, wherein the second protective layer has a thickness of 1-5 nm.

8. The semiconductor device according to claim 1, further comprising an electrode layer disposed on at least one of a lower surface and an upper surface of the selector layer.

9. A semiconductor device, comprising:
a first conductive line;
a second conductive line disposed over the first conductive line and spaced apart from the first conductive line;
a selector layer disposed between the first conductive line and the second conductive line;
a first protective layer disposed on sidewalls of the selector layer, the first protective layer including silicon (Si) and nitrogen (N) and having a nitrogen (N) content higher than a silicon (Si) content; and
a second protective layer disposed on the first protective layer, the second protective layer including silicon (Si) and nitrogen (N) and having a silicon (Si) content higher than a nitrogen (N) content.

10. The semiconductor device according to claim 9, further comprising a first electrode layer disposed between the second conductive line and the selector layer,
wherein the first protective layer is further disposed on sidewalls of the first electrode layer.

11. The semiconductor device according to claim 10, further comprising a second electrode layer disposed between the first conductive line and the selector layer,
wherein the second protective layer is disposed on the first protective layer and is further disposed on sidewalls of the second electrode layer.

12. The semiconductor device according to claim 9, wherein the first protective layer includes at least one of SiN, SiON, SiCN, or SiCON.

13. The semiconductor device according to claim 9, wherein the first protective layer has the silicon (Si) content of 30-45 at %.

14. The semiconductor device according to claim 9, wherein the first protective layer has a thickness of 1-5 nm.

15. The semiconductor device according to claim 9, wherein the second protective layer includes at least one of SiN, SiON, SiCN, or SiCON.

16. The semiconductor device according to claim 9, wherein the second protective layer has the silicon (Si) content of 50-70 at %.

17. The semiconductor device according to claim 9, wherein the second protective layer has a thickness of 1-5 nm.

18. The semiconductor device according to claim 9, further comprising an electrode layer disposed on at least one of a lower surface and an upper surface of the selector layer.
